(19) United States
(12) Patent Application Publication
(10) Pub. No.: US 2016/0084890 A1
(43) Pub. Date: Mar. 24, 2016

(54) METHOD FOR PREPARING A CURRENT MEASURING ARRANGEMENT, METHOD FOR MEASURING AN OUTPUT CURRENT, CONTROLLER, SWITCHED MODE POWER SUPPLY, AND BASE STATION

(71) Applicant: Telefonaktiebolaget L M Ericsson (publ), Stockholm (SE)

(72) Inventors: Magnus KARLSSON, Oskarshamn (SE); Vivek GANI, Austin, TX (US); Torbjorn HOLMBERG, Kalmar (SE); Oleg VOLFSON, Newton, MA (US)

(21) Appl. No.: 14/495,623

(22) Filed: Sep. 24, 2014

(51) Int. Cl. G01R 19/25

(52) U.S. Cl. CPC G01R 19/2513

(57) ABSTRACT

A method for preparing a current measuring arrangement of a switched mode power supply comprising a switched mode converter, and a controller for controlling the switched mode converter to convert an input voltage to an output voltage by means of controlling the duty cycle, is provided. A model, in which the output current of the converter is determined from variables and one or more model parameters, wherein the variables comprise the input voltage, the output voltage, and the duty cycle, is formed. The variables are varied while the output current is measured. The one or more model parameters is/are estimated from the varied variables and the measured output current by means of regression analysis and the model and the one or more estimated model parameters to be used by the current measuring arrangement during use of the switched mode power supply are stored.

### TECHNICAL FIELD

The technical field relates generally to switched mode power supplies (SMPS) and current measuring techniques in switched mode power supplies.

### BACKGROUND

Electronic systems are consuming more and more power, which requires efficient cooling. Accurate measurements of the power level of the electronic systems are therefore becoming increasingly important. The power level is typically obtained by measuring a current in the electronic system.

Existing current measuring techniques use analog-to-digital converters with fixed quantization steps creating an inaccuracy in the current measurements, which is constant over the measurement range.

### SUMMARY

The use of analog-to-digital converters with fixed quantization steps leads thus to an increasing error in the current measurements as the current is decreased. The measurement uncertainty becomes poor at light loads, where low currents are to be measured. Low currents are important to measure with high accuracy in order to be capable of controlling light load efficiency and sleep modes of the electronic systems.

It is an aim to be capable of measuring output currents, particularly low currents, with high accuracy in switched mode power supplies.

A first aspect refers to a method for preparing a current measuring arrangement of a switched mode power supply comprising a switched mode converter, and a controller for controlling the switched mode converter to convert an input voltage to an output voltage by means of controlling the duty cycle. A model is formed in which the output current of the converter is determined from variables and one or more model parameters, wherein the variables comprise the input voltage, the output voltage, and the duty cycle. The variables are varied while the output current is measured, and the one or more model parameters is/are estimated from the varied variables and the measured output current by means of regression analysis. Finally, the model and the one or more estimated model parameters to be used by the current measuring arrangement during use of the switched mode power supply are stored. The method is preferably performed by a producer of the switched mode power supply.

The one or more given model parameters are thus determined by means of design of experiment (DOE) and regression analysis.

The current measuring arrangement thus provided, preferably integrated into the controller, is capable of measuring also low output currents from the switched mode power supply with high accuracy.

The step of varying the variables while the output current is measured may comprise, for each of two of the variables, to vary the variable while the other of the two variables is kept constant and the output current is measured.

In one embodiment, a measurement range for the current measuring arrangement is selected, wherein the step of varying the variables while the output current is measured comprises to vary the variables to such extremes that the output current is varied to the extreme ends of the selected measuring range. The selected measurement range may be about 0-40%, preferably about 0-30%, and more preferably about 0-20%, of a maximum rated output current of the switched mode power supply.

Hereby, the accuracy of the current measurements is further improved.

Further, if, in the step of estimating the one or more model parameters from the varied variables and the measured output current, a set of variable and output current values is identified as an outlier, e.g. by using Cook's distance and a given threshold, such set is excluded in the estimation of the one or more model parameters.

The model may be formed in a variety of manners.

In one embodiment, the formed model is any of Iₒ=b₁(DVᵢ−Vₒ), Iₒ=b₁(DVᵢ−Vₒ)+b₂, Iₒ=b₁(DVᵢ−Vₒ)+b₂Vᵢ, or Iₒ=b₁(DVᵢ−Vₒ)+b₂Vᵢ+b₃, wherein Iₒ is the output current, D is the duty cycle, Vᵢ is the input voltage, Vₒ is the output voltage, and b₁, b₂ and b₃ are the one or more model parameters.

In another embodiment, the formed model is Iₒ=b₁DVᵢ−b₂Vₒ+b₃Vᵢ or Iₒ=b₁DVᵢ−b₂Vₒ+b₃Vᵢ+b₄, wherein Iₒ is the output current, D is the duty cycle, Vᵢ is the input voltage, Vₒ is the output voltage, and b₁, b₂, b₃, and b₄ are the one or more model parameters.

In yet another embodiment, one of the variables is a temperature. A formed model may be Iₒ=b₁(1−b₂T)(DVᵢ−Vₒ) or Iₒ=b₁(1−b₂T)(DVᵢ−Vₒ)+b₃Vᵢ or Iₒ=b₁(1−b₂T)(DVᵢ−Vₒ)+b₃Vᵢ+b₄, wherein Iₒ is the output current, T is the temperature, D is the duty cycle, Vᵢ is the input voltage, Vₒ is the output voltage, and b₁, b₃, and b₄ are the one or more model parameters, whereas b₂ is a further model parameter. The further model parameter may be determined separately in a laboratory prior to the steps of varying the variables and estimating the one or more model parameters, wherein the determined value of the further model parameter is used in the step of estimating the one or more model parameters.

The model parameter b₁, may be exchanged for a new model parameter b_{1new} in the stored one or more estimated model parameters to be used by the current measuring arrangement during use of the switched mode power supply. The model parameter b₁ may be calculated or estimated as

$${b}_{1 new} = \frac{1}{{R}_{x} + \frac{1}{{b}_{1}}} = \frac{{b}_{1}}{1 + {b}_{1} {R}_{x }} ,$$

wherein Rₓ is an external loss resistance between the switched mode power supply and the load.

This may be of particular relevance in applications, wherein the external loss resistance between the switched mode power supply and the load is not negligible, and is preferably performed by the user of the switched mode power supply.

A second aspect refers to a method for measuring an output current of a switched mode power supply comprising a switched mode converter, and a controller for controlling the switched mode converter to convert an input voltage to an output voltage by means of controlling the duty cycle. A model, in which the output current can be determined from variables and one or more given model parameters, wherein the variables comprise the input voltage, the output voltage, and the duty cycle, is retrieved. Values of the input voltage, the output voltage, and the duty cycle are retrieved. Finally, the output current is determined by means of inputting the retrieved values of the input voltage, the output voltage, and the duty cycle into the model.

The model may be formed and/or the model parameters may be determined in any of the manners disclosed above with reference to the first aspect and embodiments thereof.

The current measuring method thus provided measures output currents from the switched mode power supply with high accuracy. In particular, low currents are measured with high accuracy as compared with prior art current measuring techniques.

In one embodiment, the switched mode power supply operates in an output current range, wherein the steps of retrieving a model, retrieving values of the input voltage, the output voltage, and the duty cycle, and determining the output current are performed when an output current in a lower end of the output current range is to be measured, and another technique, such as a prior art technique based on the use of an analog-to-digital converter, is employed when an output current in a higher end of the output current range is to be measured.

Here, the benefits of each of the current measuring techniques can be obtained in an individual range of the output current.

A third aspect refers to a controller for controlling a switched mode converter of a switched mode power supply to convert an input voltage to an output voltage by means of controlling the duty cycle. The controller comprises a current measuring arrangement for measuring an output current of a switched mode power supply. The current measuring arrangement comprises a module configured to retrieve a model, in which the output current can be determined from variables and one or more given model parameters, wherein the variables comprise the input voltage, the output voltage, and the duty cycle, a module configured to retrieve values of the input voltage, the output voltage, and the duty cycle, and a module configured to determine the output current by means of inputting the retrieved values of the input voltage, the output voltage, and the duty cycle into the model.

The model and the one or more estimated model parameters may be stored in a memory of the controller.

The model may be formed and/or the model parameters may be determined in any of the manners disclosed above with reference to the first aspect and embodiments thereof.

The controller thus provided is capable of measuring output currents from the switched mode power supply with high accuracy.

A fourth aspect refers to a switched mode power supply comprising the controller of the third aspect.

A fifth aspect refers to a base station comprising one or more of the switched mode power supply of the fourth aspect.

Further characteristics and advantages will be evident from the detailed description of embodiments given hereinafter, and the accompanying FIGS. 1-5, which are given by way of illustration only.

### BRIEF DESCRIPTION OF THE DRAWINGS

FIG. 1 illustrates, schematically, in a block diagram an embodiment of a switched mode power supply.

FIG. 2 illustrates, schematically, an embodiment of a base station comprising one or more of the switched mode power supply of FIG. 1.

FIG. 3 illustrates, schematically, in a block diagram an embodiment of a controller of the switched mode power supply of FIG. 1.

FIG. 4 is a schematic flow scheme of an embodiment of a method for preparing a current measuring arrangement of the switched mode power supply of FIG. 1.

FIG. 5 is a schematic flow scheme of an embodiment of a method for measuring an output current of the switched mode power supply of FIG. 1.

### DETAILED DESCRIPTION

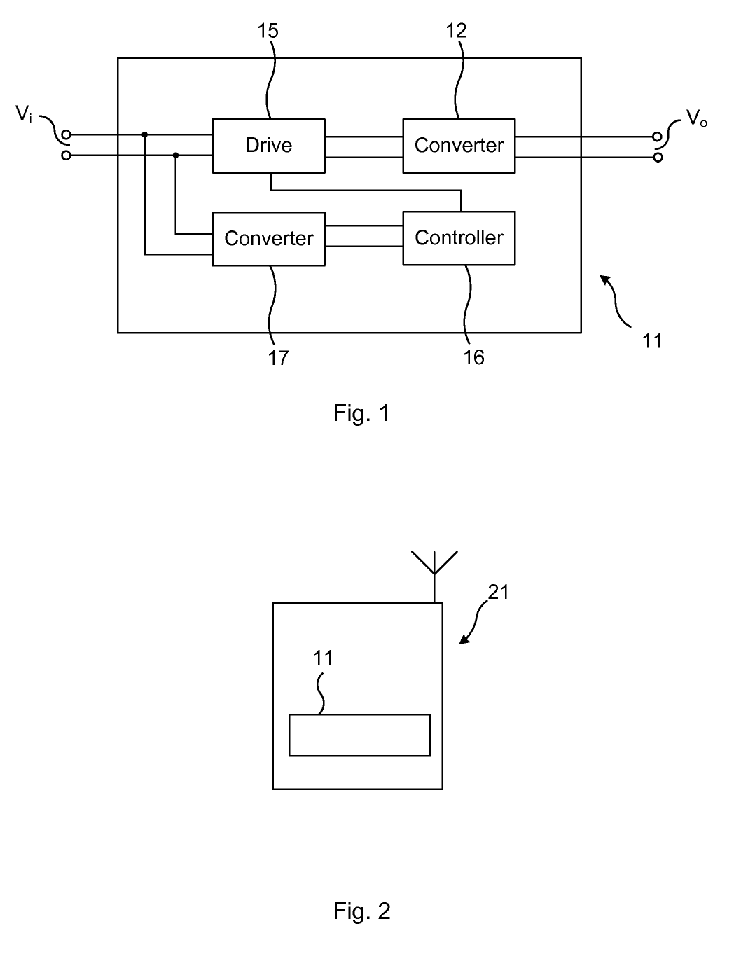

FIG. 1 illustrates, schematically, an embodiment of a switched mode power supply 11 comprising a switched mode converter 12 for converting an input voltage Vᵢ to an output voltage Vₒ, a drive 15 for driving the converter 12, a controller 16 for controlling the drive 15 and thus the operation of the converter 12, and a housekeeping or auxiliary converter 17 for down-converting the input voltage Vᵢ to a voltage suitable for the controller 16, such that the controller 16 can be powered by the input voltage Vᵢ. The controller 16 controls the drive 15 such that a selected output voltage Vₒ is obtained by means of controlling the duty cycle D of drive 15 and converter 12.

The converter 12 may be an isolated buck, non-isolated buck, boost, inverter based, full-bridge, half-bridge, fly-back, forward, or fly-forward converter typically down-converting the input voltage Vᵢ to a suitable output voltage Vₒ. The converter 12 may typically operate with input Vᵢ and output Vₒ DC voltages in the range of 4-400 V. The drive 15 may comprise a pulse width modulator.

FIG. 2 illustrates, schematically, an embodiment of a base station 21 comprising one or more of the switched mode power supply 11 of FIG. 1.

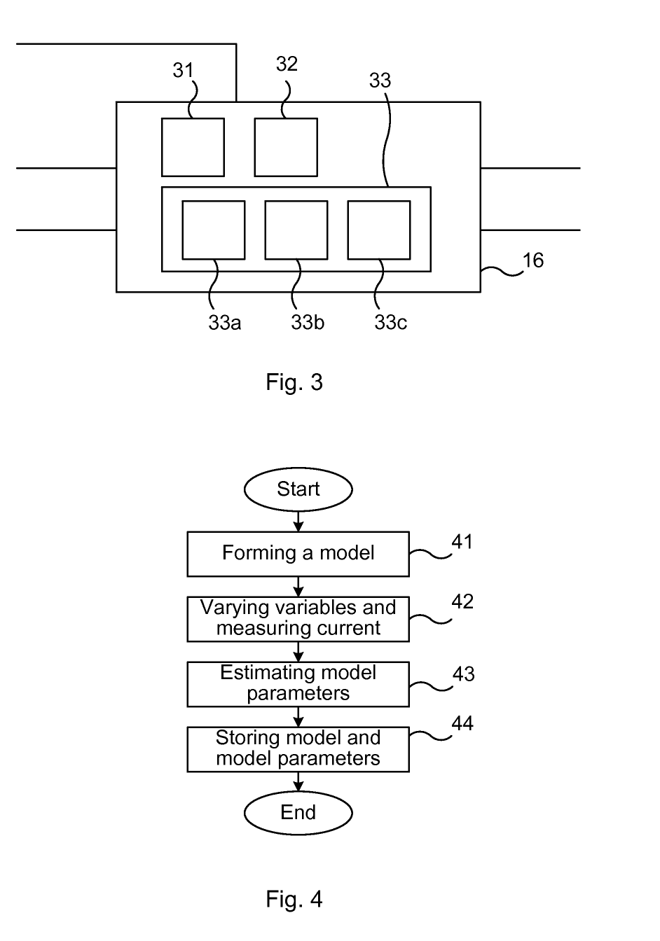

FIG. 3 illustrates, schematically, in a block diagram an embodiment of a controller 16 of the switched mode power supply 11 of FIG. 1. The controller comprises a module 31 for the control of the drive 15, a memory 32, and a current measurement arrangement 33.

The current measuring arrangement 33 comprises a module 33a configured to retrieve a model, in which the output current Iₒ can be determined from variables and one or more given model parameters, wherein the variables comprise the input voltage Vᵢ, the output voltage Vₒ, and the duty cycle D, a module 33b configured to retrieve values of the input voltage Vᵢ, the output voltage Vₒ, and the duty cycle, and a module 33c configured to determine the output current Iₒ by means of inputting the retrieved values of the input voltage Vᵢ, the output voltage Vₒ, and the duty cycle D into the model.

In some embodiments, the controller is a digital controller based on a digital computer, microcontroller, or an electric circuit such as an ASIC.

The model, the variables, and the one or more given model parameters will be described further below.

During ideal conditions, the output voltage Vₒ of the converter 12 is dependent on the duty cycle, D and the input voltage Vᵢ as

Vₒ=DVᵢ (Eq. 1)

The first order model is accomplished by adding a current depending voltage loss resistance Rₗₒₛₛ as

Vₒ=DVᵢ−RₗₒₛₛIₒ (Eq. 2)

Eq. 2 can be rewritten such that the current Iₒ is given as

$${I}_{o} = \frac{1}{{R}_{loss}} ( {DV}_{i} - {V}_{o} ) \qquad ( Eq . 3 )$$

Design of experiment (DOE) is an approach in statistics. A model is formed with variables and model parameters. In Eq. 4 an example with two independent variables is shown.

Y=b₁X₁+b₂X₂+b₃X₁X₂ (Eq. 4)

where X₁ and X₂ are the variables, b₁, b₂, and b₃ are model parameters or coefficients, and Y is the result to be measured.

Generally, by using a minimal number of measurements, and varying one variable Xᵢ of the model at a time, recording the result Y, and using regression analysis, e.g. a least square method, errors in the model can be minimized by adjusting the model parameters bᵢ.

For the example of Eq. 4, measurements are performed at the extreme values of each variable (denoted with value 1 and as described in the Table 1) covering the worst case values of the variables.

TABLE 1
Variable values for DOE

| X₁ | X₂ |
|---|---|
| 1 | 1 |
| 1 | 2 |
| 2 | 1 |
| 2 | 2 |

FIG. 4 is a schematic flow scheme of an embodiment of a method for preparing a current measuring arrangement of the switched mode power supply of FIG. 1.

Generally, a model, in which the output current Iₒ of the converter is determined from variables and model parameters b₁, b₂, . . . , wherein the variables comprise the input voltage Vᵢ, the output voltage Vₒ, and the duty cycle D, is formed, at block 41. The variables are varied, at block 42, while the output current is measured. The model parameters are estimated, at block 43, from the varied variables and the measured output current by means of regression analysis. Finally, the model with the estimated model parameters to be used by the current measuring arrangement 33 during use of the switched mode power supply 11, are, in block 44, stored, e.g. in the memory 32 of the controller 16.

Block 42 may, for each of two of the variables, e.g. the input Iₒ and output Iₒ voltages, include varying the variable while the other of the two variables is kept constant and the output current is measured. Note that the three variables input voltage Vᵢ, output voltage Vₒ, and duty cycle D are not independent variables, and therefore typically two of them are varied in a controlled manner, whereas the third variable will depend on the first to variables.

In one version, a measurement range for the current measuring arrangement 33 is selected. The selected measurement range may be about 0-40%, preferably about 0-30%, and more preferably about 0-20%, of a maximum rated output current of the switched mode power supply 11. The step 42 may here comprise varying the variables to such extremes that the output current is varied to the extreme ends of the selected measuring range.

Various models can be used in the method described above, which uses DOE and regression analysis to determine the model parameters of a selected model.

Using the physical model in Eq. 3 as a base, a simple model, which yields a large correlation factor R between the measured data and model and a small root-mean-square (RMS) error, can be selected by trial and error:

Iₒ=b₁(DVᵢ−Vₒ)+b₂Vᵢ (Eq. 5)

In a DOE with small number of measurements it may be important to keep the number of parameters at a minimum, or otherwise the uncertainty/variance in the estimates increases despite the RMS error in the model being low.

Using eight exemplary sample sets for the model in Eq. 5, a correlation factor R=0.9766 can be obtained for a non-isolated buck converter with an input voltage Vᵢ range of 11-13 V, an output voltage Vₒ, of about 1 V, and a maximum current Iₒ of 20 A, where 1 corresponds to 100% correlation. Using this model, the error can be up to 10% at a current of 2 A.

Experiments show that with this low number of samples, one outlier can be handled improving the model without decreasing the uncertainty in the model parameters much.

Another exemplary model is Eq. 5, from which the last term is removed.

When the number of samples is increased, a further number of model parameters will improve the accuracy. For instance, if (DVᵢ−Vₒ) is decoupled, two different model parameters b₁, b₂ for these variable combinations can be employed. Further a constant b₄ may be added. The result is

Iₒ=b₁DVᵢ−b₂Vₒ+b₃Vᵢ+b₄ (Eq. 6)

Another exemplary model is Eq. 6, from which the last term, i.e. the constant, is removed.

Experiments show that using the model of Eq. 6 and basing the regression analysis on an exemplary 16 sample sets for the above disclosed non-isolated buck converter, a correlation factor of R=0.9818 can be obtained, and the error can be up to 5% at 2 A.

If the number of sample sets is increased to 41, the correlation factor R can be increased to 0.992 and the error is decreased to 3% at 2 A.

In the estimation of the model parameter(s) from the varied variables and the measured output current, at least one set of variable and output current values may be identified as an outlier, e.g. by using Cook's distance and a threshold, and may be excluded in the estimation of the model parameter(s).

Furthermore, a temperature T compensation can be added to the models above yielding e.g. for Eq. 2:

Vₒ=DVᵢ−Rₗₒₛₛ(1+kT)Iₒ (Eq. 7)

Eq. 7 can be rewritten such that the current Iₒ is given as

$${I}_{o} = \frac{1}{{R}_{loss} ( 1 + kT )} ( {DV}_{i} - {V}_{o} ) \qquad ( Eq . 8 )$$

The model in Eq. 8 can be directly used, but the division is costly in terms of calculation later on using the model. In order to avoid the division the first order approximation can be used yielding the following model, which also includes the separate Vᵢ term from Eq. 5.

Iₒ=b₁(1−b₂T)(DVᵢ−Vₒ)+b₃Vᵢ (Eq. 9)

In order to make it possible to use in mass production in some embodiments the temperature coefficient should be determined in a laboratory and the model parameter or coefficient b₂ in Eq. 9, should be treated as a constant during the estimation of the model parameters during the regression analysis. The temperature is, however, still measured in the DOE.

In production only the internal losses can be accounted for. In real life applications, the external loss resistance Rₓ between the switched mode power supply 11 and the load also affects the duty cycle D. The two resistances are coupled in series.

Comparing Eqs. 3 and 5 gives the internal loss resistance Rₗₒₛₛ as the reciprocal of the model parameter b₁

$${R}_{loss} = \frac{1}{{b}_{1 }} \qquad ( Eq . 10 )$$

Hence, a new model parameter b_{1new} can be calculated and used instead of b₁ in the particular application.

$${b}_{1 new} = \frac{1}{{R}_{x} + \frac{1}{{b}_{1 }}} = \frac{{b}_{1}}{1 + {b}_{1} {R}_{x }} \qquad ( Eq . 12 )$$

The external loss resistance Rₓ can be estimated or measured in any manner, and the model parameter b₁ is exchanged for the new model parameter b_{1new} before using the switched mode power supply 11 in the particular application.

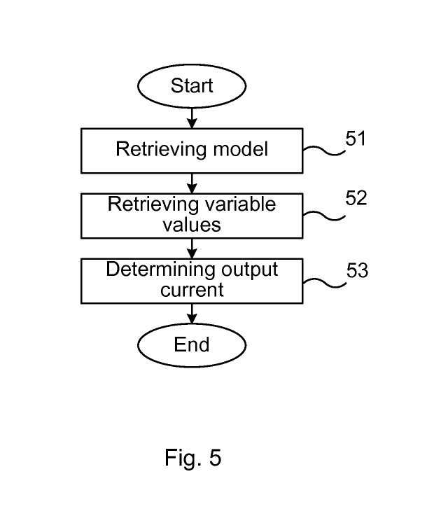

FIG. 5 is a schematic flow scheme of an embodiment of a method for measuring an output current Iₒ of the switched mode power supply of FIG. 1. A model is retrieved, in block 51, e.g. from the memory 32 of the controller 16, in which a model the output current can be determined from variables and one or more given model parameters, wherein the variables comprise the input voltage, the output voltage, and the duty cycle. Values of the input voltage, the output voltage, and the duty cycle are retrieved, in block 52. In some embodiments, at least the output voltage Vₒ and the duty cycle D should be known by the controller 16. If the input voltage Vᵢ is not known, it can be measured by any technique known in the art. The output current is determined, in block 53, by means of inputting the retrieved values of the input voltage, the output voltage, and the duty cycle into the model.

The one or more given model parameters may have been determined by DOE and regression analysis as disclosed above.

In one embodiment, the switched mode power supply operates in an output current range, e.g. between o and a maximum rated current of the switched mode power supply, wherein the method in blocks 51-53 is performed when an output current in a lower end of the output current range is to be measured, whereas another technique, e.g. a method involving the use of an analog-to-digital converter, is employed when an output current in a higher end of the output current range is to be measured. Whether the output current is in a lower or in a higher end of the output current range corresponds to the switched mode power supply being operated at low or high power and may be known by the controller. Otherwise, it may be measured by any arrangement known in the art.

It shall be appreciated by a person skilled in the art that the embodiments disclosed herein are merely example embodiments, and that any details and measures are purely given as examples.

What is claimed is:

1. A method for preparing a current measuring arrangement of a switched mode power supply comprising a switched mode converter, and a controller for controlling the switched mode converter to convert an input voltage to an output voltage by controlling the duty cycle, comprising:
forming a model, in which the output current of the converter is determined from variables and one or more model parameters, and wherein the variables comprise the input voltage, the output voltage, and the duty cycle;
varying the variables while the output current is measured;
estimating the one or more model parameters from the varied variables and the measured output current by regression analysis; and
storing the model and the one or more estimated model parameters to be used by the current measuring arrangement during use of the switched mode power supply.

2. The method of claim 1 wherein the varying the variables while the output current is measured comprises, for each of two of the variables, varying the variable while the other of the two variables is kept constant and the output current is measured.

3. The method of claim 1, wherein,
a measurement range for the current measuring arrangement is selected; and
the varying the variables while the output current is measured comprises varying the variables to such extremes that the output current is varied to the extreme ends of the selected measuring range.

4. The method of claim 1, wherein the selected measurement range is 0-40% of a maximum rated output current of the switched mode power supply.

5. The method of claim 1, wherein the estimating the one or more model parameters from the varied variables and the measured output current further comprises identifying at least one set of variable and output current values as an outlier by using Cook's distance and excluding the identified variables from the estimation of the one or more model parameters.

6. The method of claim 1, wherein the formed model is at least one of Iₒ=b₁(DVᵢ−Vₒ), Iₒ=b₁(DVᵢ−Vₒ)+b₂, Iₒ=b₁(DVᵢ−Vₒ)+b₂Vᵢ, and Iₒ=b₁(DVᵢ−Vₒ)+b₂Vᵢ+b₃, wherein Iₒ is the output current, D is the duty cycle, Vᵢ is the input voltage, Vₒ is the output voltage, and b₁, b₂ and b₃ are the one or more model parameters.

7. The method of claim 1, wherein the formed model is at least one of Iₒ=b₁DVᵢ−b₂Vₒ+b₃Vᵢ and Iₒ=b₁DVᵢ−b₂Vₒ+b₃Vᵢ+b₄, wherein Iₒ is the output current, D is the duty cycle, Vᵢ is the input voltage, Vₒ is the output voltage, and b₁, b₂, b₃, and b₄ are the one or more model parameters.

8. The method of claim 1 wherein at least one of the one or more variables comprises a temperature.

9. The method of claim 8, wherein the formed model is at least one of Iₒ=b₁(1−b₂T)(Dvᵢ−Vₒ), Iₒ=b₁(1−b₂T)(Dvᵢ−Vₒ)+b₃Vᵢ, and Iₒ=b₁(1−b₂T)(DVᵢ−Vₒ)+b₃Vᵢ+b₄, wherein Iₒ is the output current, T is the temperature, D is the duty cycle, Vᵢ is the input voltage, Vₒ is the output voltage, and b₁, b₃, and b₄ are the one or more model parameters, and b₂ is a further model parameter.

10. The method of claim 9 wherein the further model parameter is determined separately in a laboratory prior to the varying the variables and the estimating the one or more model parameters.

11. The method of claim 6, wherein the switched mode power supply is connected to a load, and the estimated model parameter b₁ is exchanged for a new model parameter b_{1new}, wherein b_{1new} is calculated as
$${b}_{1 new} = \frac{1}{{R}_{x} + \frac{1}{{b}_{1}}} = \frac{{b}_{1}}{1 + {b}_{1} {R}_{x }} ,$$
and wherein Rₓ is an external loss resistance between the switched mode power supply and the load.

12. A method for measuring an output current of a switched mode power supply comprising a switched mode converter and a controller for controlling the switched mode converter to convert an input voltage to an output voltage by controlling the duty cycle (D), comprising:
retrieving a model, in which the output current can be determined from variables and one or more given model parameters, wherein the variables comprise the input voltage, the output voltage, and the duty cycle;
retrieving values of the input voltage, the output voltage, and the duty cycle; and
determining the output current by means of inputting the retrieved values of the input voltage, the output voltage, and the duty cycle into the model.

13. The method of claim 12 wherein the one or more given model parameters are determined by design of experiment (DOE) and regression analysis.

14. The method of claim 12, wherein,
the switched mode power supply operates in an output current range; and
the retrieving a model, the retrieving values of the input voltage, the output voltage, and the duty cycle, and the determining the output current are performed only when measuring an output current in a lower end of the output current range.

15. A controller for controlling a switched mode converter of a switched mode power supply to convert an input voltage to an output voltage by means of controlling the duty cycle, comprising a current measuring arrangement for measuring an output current of a switched mode power supply, the current measuring arrangement comprising:
a first module configured to retrieve a model, in which the output current can be determined from variables and one or more given model parameters, wherein the variables comprise the input voltage, the output voltage, and the duty cycle;
a second module configured to retrieve values of the input voltage, the output voltage, and the duty cycle; and
a third module configured to determine the output current by means of inputting the retrieved values of the input voltage, the output voltage, and the duty cycle into the model.

16. The controller of claim 15, wherein the one or more given model parameters are determined by regression analysis of a design of experiment (DOE).

17. The controller of claim 15, wherein the model and the one or more estimated model parameters are stored in a memory of the controller.

18. The controller of claim 15, wherein the one or more given model parameters are determined by an experiment, in which the variables are varied while the output current is measured, and the one or more model parameters are determined from the varied variables and the measured output current by regression analysis.

19. The controller of claim 18, wherein the current measuring arrangement has a measurement range and wherein the variables are varied, in the experiment such that the output current is varied to the extreme ends of the selected measuring range.

20. The controller of claim 15, wherein the current measuring arrangement has a measurement range of 0-40% of a maximum rated output current of the switched mode power supply.

21. The controller of claim 15, wherein,
the switched mode power supply operates in an output current range; and
the first module is configured to retrieve a model, the second module is configured to retrieve values of the input voltage, the output voltage, and the duty cycle, and the third module is configured to determine the output current by inputting the retrieved values of the input voltage, the output voltage, and the duty cycle into the model when an output current in a lower end of the output current range is to be measured, and another current measuring device is employed when an output current in a higher end of the output current range is to be measured.

22. The controller of claim 15, wherein the controller is part of a switched mode power supply with a switched mode converter capable of converting an input voltage to an output voltage, wherein the output voltage is dependent on the input voltage and a duty cycle employed.

23. The controller of claim 22, wherein the switched mode converter is a DC-DC converter.

24. The controller of claim 22, wherein the switched mode converter is configured to operate with input and output voltages in the range of 4-400 V.

25. The controller of claim 22, wherein the switched mode power supply is further part of a base station.
